(19) United States
(12) Patent Application Publication
(10) Pub. No.: US 2014/0256083 A1
(43) Pub. Date: Sep. 11, 2014

(54) High Speed Copper Plating Process

(71) Applicant: MACDERMID ACUMEN, INC, Waterbury, CT (US)

(72) Inventors: Eric Yakobson, Aliso Viego, CA (US); Adam Letize, Wallingford, CT (US); Kenneth Crouse, Newington, CT (US)

(73) Assignee: MACDERMID ACUMEN, INC., Waterbury, CT (US)

(21) Appl. No.: 13/786,728

(22) Filed: Mar. 6, 2013

(51) Int. Cl. H01L 31/18

(52) U.S. Cl. CPC H01L 31/18
USPC 438/98

(57) ABSTRACT

A copper electrolyte comprising a copper nitrate salt is described. The electrolyte is suitable for use in a light induced plating process for metallizing contacts in a photovoltaic solar cell. A method of metallizing an electrical contact in a photovoltaic solar cell using the copper electrolyte is also described.

### FIELD OF THE INVENTION

The present invention relates generally to improved copper plating electrolytes useful for manufacturing photovoltaic (PV) cells.

### BACKGROUND OF THE INVENTION

Photovoltaic (PV) devices are semiconductor devices that convert light energy to useful electrical energy. Typical PV devices include solar cells, which are configured to convert the energy from the sun to electrical energy. The typical PV solar cell comprises a semiconductor substrate having a P-N junction near its front energy-receiving surface, a grid-shaped contact or electrode and an SiNx anti-reflection coating on the front energy-receiving surface and a second contact or electrode on its rear surface.

Typically, the solar cell is made of P-type silicon and a diffusion region in the upper portion the substrate, to create the junction. The grid contact typically comprises a number of evenly spaced fingers connected together by one or more metal bus bars. The electrons travel directly to the metal fingers or else travel in the direction of the upper surface and then travel along the upper surface to where they can be collected by the fingers. The grid may be made of various metals, such as silver. The bottom or back contact is commonly made of aluminum.

The majority of PV cells currently in production are based on silicon wafers with screen printed metal pastes as electrical contacts. Screen printing is attractive due to its simplicity in processing and high throughput capability. However, there are several notable disadvantages including high contact resistance, high paste cost, shadowing from wide conductive lines, high temperature processing and mechanical yield loss, which have not yet been overcome.

Thus, while silver thick film conductive paste screen-printing is one of the most widely used methods for contact formation on commercial PV cells, it has also become a major impediment to conversion efficiency improvement as well as a substantial material cost escalating factor in the solar cell processing sequence. Although conductivity of silver is the highest of all metals, the cost of this noble metal is disproportionately high for the conductivity gain in relation to the cost of other highly conductive metals such as copper.

Furthermore, fired silver paste is not 100% solid silver metal. Commercial conductive silver pastes are proprietary blended compositions that, along with the conductive silver metal powder, contain a substantial amount of glass frit, as described for example in U.S. Pat. No. 7,935,279 to Prunchak, the subject matter of which is herein incorporated by reference in its entirety. The function of the glass frit is to make a bond as well as to ensure ohmic contact with the underlying silicon upon firing. Glass frit comprises primarily of lead oxide and may also contain other metal oxides, including cadmium, bismuth, etc. Additives may be used as additional dopants. On firing, the paste does not form a perfectly solid silver metal conductor. Therefore, the conductivity of fired silver paste is up to 2.5 times lower than that of silver metal. However, its cost, as a commercial proprietary product, is higher than that of silver metal.

There has been an ongoing effort in the industry to improve the efficiency of industrial solar cells and one key focus has been the reduction of contact resistance of the front face electrical contacts. It has generally been accepted that the contact formation of conventional screen printed silver pastes to the front face of PV solar cells involves a complex series of interactions between the glass, silver, silicon nitride and silicon and that the sequence and rates of reactions occurring the during the firing process are factors in forming the contact between the silver paste and the silicon. In addition, the presence of glass at the metal-silicon interface inevitably results in a higher contact resistance than would be realized by a pure metal contact to silicon.

Thus, through the years, numerous attempts have been made within the PV industry to replace screen-printed silver paste metallization with other processes such as wet electrodeposition processes. Various wet electrodeposition processes are described, for example, in U.S. Pat. No. 4,144,139 to Durkee, U.S. Pat. No. 4,251,327 to Grenon, U.S. Pat. No. 4,321,283 to Patel et al., U.S. Pat. No. 4,612,698 to Gonsiorawski et al., U.S. Pat. No. 5,011,565 to Dube et al., U.S. Pat. No. 5,882,435 to Holdermann, and U.S. Pat. No. 7,955,978 to Cahalen et al., the subject matter of each of which is herein incorporated by reference in its entirety.

The cost of the materials that comprise PV cells is not merely a profit-defining monetary consideration for PV cell manufacturers. It also has a profound impact on the development of the PV industry. In order to reach so-called grid parity with conventional (i.e., ˜70% fossil fuel-based) energy sources, PV energy cost per watt must be reduced below the level of fossil fuel-based energy cost. One way to accomplish this is by reducing material/manufacturing costs of PV cells while increasing their energy conversion efficiency.

The conductivity of copper metal is only about 5.7% lower than the conductivity of silver metal, thus it takes only about a 5.7% thicker conductor to compensate for the difference in conductivity in order to obtain the equivalent to silver conductivity for a given conductor cross-section. On the other hand, at the present time, the cost of copper metal is approximately 140 times lower than the cost of silver metal. Furthermore, copper metal is both more conductive than proprietary silver paste compositions and is orders of magnitude less expensive.

Moreover, silver paste also suffers from numerous limitations of conventional screen-printing technology, including low screen resolution, low aspect ratio, and inefficient glass-frit contact to the underlying doped silicon emitter. Finally silver paste firing typically involves a high temperature sintering step that may cause micro-cracks, bowing, and degradation of the passivation layers. Firing is typically carried out at temperatures in the range of up to 900° C. to achieve low series resistance. However, high temperature exposure can lead to ohmic junction shunting and recombination, which degrades the fill factor, thereby reducing the energy conversion efficiency, which in turn increases the cost per watt.

There are a number of reasons why copper has not been widely adapted by the PV industry as a contact formation material of choice, either as the main conductor in screen-printing pastes or as an electroplated metal, including:
1) Copper is not suitable as the conductor metal for screen-printing paste compositions. If left unprotected, it easily forms non-conductive oxides on its surface in the ambient atmosphere and rapidly oxidizes at elevated temperatures, which would render the paste non-conductive upon firing;
2) Copper is considered to be a poison for silicon and therefore cannot be used for direct ohmic contact formation as it will diffuse and migrate into the silicon;
3) One of the most significant reasons that copper has not been used as the main conductor is that there are a limited number of available commercial wet electroplating high-volume manufacturing (HVM)-capable types of copper electroplating processes. Furthermore, none of the currently available commercial copper processes on the market today have been easily adaptable for PV applications.

The inventors of the present invention have determined that if a copper conductor is isolated from the underlying silicon layer by a diffusion barrier layer capable of forming a low-resistivity ohmic contact and is also protected from oxidation by a solderable final finish coating, it would present a highly technologically advantageous, more cost effective, and highly conductive alternative to screen-printed silver contact formation techniques. Furthermore, even if only a substantial part of the silver paste on a PV cell is replaced with copper, it may still be technologically and economically advantageous.

However, the inventors here have determined that in order for copper plating electrolytes to be suitable for high-volume manufacturing (HVM) of commercial grade PV cells, the following design manufacturing requirements must be met:

The copper-plating electrolyte should not:
1) Attack the substrate or diffusion barrier interface;
2) Be extremely acidic or alkaline;
3) Contain any ions that would be aggressive to amphoteric metal oxides (e.g., lead, cadmium, bismuth or zinc oxides that might be part of a silver paste composition) or promote dissolution of Si/SiO₂ (e.g., F⁻ or NH₄⁺); or
4) Attack the SiNx anti-reflective coating or leave behind any poorly rinseable residue of the SiNx anti-reflective coating that might affect emitter PV properties.

Furthermore, the copper-plating electrolyte should:
1) Have a high enough plating rate so as to deposit a reproducible copper thickness in a short amount of time (i.e., up to 5 μm/min);
2) Exhibit a high enough concentration of copper ions in the electrolyte to ensure high current density (HCD) performance without sacrificing distribution;
3) The copper salt used as a cupric ion source should have high solubility;
4) Be conductive enough for low voltage and good metal distribution;
5) Be easily rinseable from a SiNx anti-reflective coating; and
6) Optical density of the electrolyte should allow for a light-induced plating (LIP) mode.

The inventors of the present invention have found that a new type of copper electrolyte based on copper nitrate provides advantages over other copper electrolytes, especially in the area of manufacturing PV cells. In addition, the inventors have also found the copper electrolyte described herein can provide a good result when used in an LIP process in the manufacture of PV cells.

### SUMMARY OF THE INVENTION

It is an object of the present invention to provide an improved copper electrolyte that can be used for plating grid contacts on a photovoltaic solar cell at high current densities while maintaining the cathode efficiency.

It is another object of the present invention to provide an improved copper electrolyte that allows for light induced plating (LIP) in the manufacture of photovoltaic solar cells.

another object of the present invention to provide an improved method of making grid contacts for semiconductor solar cells.

It is still another object of the present invention to provide a method of making electrical contacts on solar cells that involves light induced plating (LIP) a layer of copper.

To that end, in one embodiment the present invention relates generally to an improved copper electrolyte comprising a copper salt, wherein said copper salt is a copper nitrate salt, and wherein said electrolyte is suitable for use in a light induced plating process for metallizing contacts in a photovoltaic cell.

In another embodiment, the present invention relates generally to a method of plating an electrical contact on a semiconductor solar cell substrate, wherein a first surface of the semiconductor solar cell substrate is covered with an anti-reflection coating and a second surface of the semiconductor solar cell substrate comprises a back electrode, wherein a grid pattern is formed in the anti-reflection coating comprising portions with the anti-reflection coating and portions without anti-reflection coating, and a barrier metal is deposited on the grid pattern formed in the anti-reflection coating in the portions without the anti-reflection coating either directly on the semiconductor solar cell substrate or on a silver paste, wherein copper metal is plated on the barrier metal by a process comprising the steps of:
a) immersing the semiconductor solar cell substrate in an electrolyte comprising a copper nitrate salt and wherein an anode is also immersed in the electrolyte; and
b) causing the barrier metal to become cathodic by (i) exposing the first surface of the semiconductor solar cell substrate to electromagnetic radiation to generate a photovoltaic response and cause the semiconductor solar cell substrate to generate current in the electrolyte and/or (ii) applying an external current;
wherein copper metal is plated on the barrier metal;
   and wherein the grid pattern is formed by either by (i) directly removing selected portions of the anti-reflection coating, or by (ii) printing a silver paste in the image of the grid pattern on the anti-reflection coating and heating the semiconductor solar cell substrate to cause the silver paste to penetrate the anti-reflection coating.

The silver paste itself, if used, may act as the barrier metal.

### DETAILED DESCRIPTION OF THE PREFERRED EMBODIMENTS

The HVM-capable copper plating electrolyte of this invention for PV applications typically comprises a copper salt, a conductivity carrier, and various buffers and additives that may control internal stress, deposit morphology and metal distribution.

In order to serve as the Cu²⁺ ion source, the copper salt should be highly soluble, be inexpensive, be stable under electrolysis conditions, with little or no by-products, and should be easily replenishable by anode dissolution.

The conductivity carrier used herein reduces voltage and increases the throwing power and metal distribution. In addition, the conductivity carrier used herein is highly soluble, inexpensive and stable under hydrolysis condition, with no-consumption other than by drag-out and little or no by-products. Suitable conductivity carriers include salts of nitrate, sulfate, sulfonate, methane sulfonate, phosphate and the like. Most preferred are sodium or potassium salts of the foregoing anions.

The electrolyte used herein is well buffered against any pH fluctuations caused by drag-out and/or less than 100% cathode/anode efficiency. In addition, the buffering system does not interfere with plating but should preferably improve the quality of the copper deposit.

Various additives may also be added to control stress, deposit morphology and metal distribution and may include, for example, suppressors, accelerators, and cuprous ligands. A suppressor may be added to increase throwing power, thereby improving metal distribution and should work synergistically with the accelerator. The primary function of the accelerator is to reduce internal stress. In addition, the accelerator should provide for uniform deposit morphology and cosmetic uniformity. Suitable suppressors include polyethylene glycols, polypropylene glycols, ethylene oxide-propylene oxide copolymers and the like. Suitable accelerators include organic disulfides, organic thio compounds and organic mercapto compounds such as those sold by the Raschig Company. The cuprous ligand should ensure adsorption of the suppressor on the copper surface during the electrolysis process. In addition, the cuprous ligand should improve morphology, physical properties of the copper and cosmetic uniformity. The cuprous ligand should also work synergistically with the suppressor and accelerator. Suitable cuprous ligands include chloride and bromide salts. The buffer, suppressor, accelerator and cuprous ligands should all be consumed primarily by drag-out. Appropriate buffer systems include sodium or potassium salts with acetate, malonate, tartrate and succinate.

The electrolyte composition used herein is such that the cathode current efficiency is preferably greater than about 80% in the highest current density areas and approaching 100% in the lowest current density areas for better metal distribution. The anode efficiency preferably approaches 100%.

By-products and contaminants are easily removable by conventional batch peroxide/carbon treatment, more preferably, purification is by carbon polishing. Most preferably, the electrolyte system has an infinite electrolyte life without the need for any purification.

All of the electrolyte components are analyzable by volumetric and electrochemical (CVS) analysis methods. In addition, the electrolyte does not contain any cyanides, heavy chelators, known or suspected carcinogens, mutagens, teratogens, reproductive/aquatic life toxins, fluorides, ammonia, flammables or VOCs. Waste treatment is relatively straightforward, preferably as easy as adding sodium hydroxide to a pH of greater than 7, precipitating Cu(OH)₂ and then filtering.

In order to provide an HVM-capable copper plating electrolyte for PV applications, the inventors of the present invention have discovered an improved copper plating electrolyte comprising a copper salt, wherein said copper salt is a copper nitrate salt, and wherein said electrolyte is suitable for use in a light induced plating process for metallizing contacts in a photovoltaic cell.

Copper nitrate is a widely available, inexpensive copper salt, but as yet has not been utilized as the main cupric ion source in commercial electroplating baths. Copper nitrate has high solubility in water (1360 grams of copper nitrate hemi(pentahydrate) per 1 liter of water at 20° C.), which allows for a high concentration of copper ions to be available for electroplating at high current density (HCD). In contrast, the solubility of copper sulfate is much lower (320 grams per 1 liter of water at 20° C.). Copper nitrate may be anhydrous and also occurs as five different hydrates. In one preferred embodiment, the copper nitrate is used in the form of copper nitrate hemi(pentahydrate).

The amount of copper nitrate added to the electrolyte is preferably based on the desired concentration of copper ions. In a preferred embodiment, the concentration of copper ions in the electrolyte is between about 10 g/L and about 150 g/L, more preferably between about 20 g/L and about 100 g/L.

In addition, the copper electrolyte also comprises potassium nitrate or sodium nitrate as conductivity carrier. Preferably the concentration of potassium nitrate or sodium nitrate in the electrolyte is between about 100 g/L and about 150 g/L, more preferably between about 110 g/L and about 130 g/L. The copper electrolyte also typically comprises a source of chloride additives as an additional conductivity carrier.

The pH of the copper electrolyte is typically maintained between about 1 and 4.

Copper nitrate has a unique property that is different from all of the conventional copper salts that are currently in use today. The nitrate ion, being an oxidizer, is capable of being reduced at the cathode at extreme HCD (i.e., above the limiting current density) where normally hydrogen evolution begins to occur in conventional acid copper plating baths based on sulfuric acid, methane sulfonic acid or fluoboric acid. Hydrogen evolution is a secondary electrochemical reaction participating in the electroplating process that indicates a drop in cathode current efficiency that is caused by insufficient cupric ion concentration supply available for the deposit nucleation at a given applied current density within the cathode boundary layer. This results in so-called “burnt” loosely-adherent powdery dendritic blackened deposit that is a mixture of cupriacuprous oxides with copper metal and is unsuitable for any functional applications. However, in the proposed nitrate-based copper electrolyte described herein, the working HCD limit is significantly expanded relative to a given cupric ion concentration, which allows for higher current density electrodeposition without any evidence of “burn.” HCD plating is especially technologically and economically advantageous for high speed, high productivity applications such as the manufacturing of PV cells.

More importantly, the pH of copper nitrate solutions is not nearly as acidic as the pH of conventional acid copper electrolytes that are based on free sulfuric acid, methane sulfonic acid or fluoboric acid. Furthermore, unlike conventional acid copper electrolytes, copper electrolytes based on copper nitrate, as described herein, do not necessitate additions of free sulfuric acid and can be successfully operated at higher pH values. In fact, it is generally preferable that the pH is buffered at a less acidic pH in order to avoid any pH fluctuations due to drag-in/drag-out. Since the proposed electrolyte is operated at a low acidity, it does not exhibit any evidence of chemical attack on either silicon or the nickel diffusion barrier interface. Therefore, high adhesion of the whole metal stack can be ensured, which has been impossible to achieve with conventional acid copper electrolytes.

Thus, in another embodiment, the present invention relates generally to a method of plating an electrical contact on a semiconductor solar cell substrate, wherein a first surface of the semiconductor solar cell substrate is covered with an anti-reflection coating and a second surface of the semiconductor solar cell substrate comprises a back electrode, wherein a grid pattern is formed in the anti-reflection coating comprising portions with the anti-reflection coating and portions without anti-reflection coating, and a barrier metal is deposited on the grid pattern formed in the anti-reflection coating on the portions without the anti-reflection coating either directly on the semi-conductor solar cell substrate or on a silver paste, wherein copper metal is plated on the barrier metal by a process comprising the steps of:
a) immersing the semiconductor solar cell substrate in an electrolyte comprising a copper nitrate salt and wherein an anode is also immersed in the electrolyte; and
b) causing the barrier metal to become cathodic by (i) exposing the first surface of the semiconductor solar cell substrate to electromagnetic radiation to generate a photovoltaic response and cause the semiconductor solar cell substrate to generate current in the electrolyte and/or (ii) applying an external current;

wherein copper metal is plated on the barrier metal;

and wherein the grid pattern is formed by either by (i) directly removing portions of the anti-reflection coating, or by (ii) printing a silver paste in the image of the grid pattern on the anti-reflection coating and heating the semiconductor solar cell substrate to cause the silver paste to penetrate the anti-reflection coating.

The silver paste itself if used, may act as the barrier metal.

Electrical contacts are made between the barrier metal and the anode, preferably through an external power source, and indirectly through the electrolyte.

A final finish comprising plating (i) a metal more noble than copper or (ii) tin over the copper is preferred. Most, preferably, a final finish of silver may be deposited over the plated copper deposit. Silver may be plated by immersion silver plating, electroless silver plating or electrolytic silver plating.

The barrier metal is preferably selected from the group consisting of nickel, cobalt, palladium and platinum. In a preferred embodiment, the barrier metal is nickel. The barrier metal may be deposited by electroless plating or by light induced electroless plating or by electrolytically assisted electroless plating. The nickel layer may optionally, but preferably be deposited in a light induced plating process. The barrier metal is selected from the group consisting of a single electroplated, LIP- or autocatalytically-deposited (electroless deposition) metal or an alloy known to exhibit diffusion barrier properties comprising one or more metals selected from the group: Ni, Co, Pd, W, Mo, Re, platinum and Cr. and alloys of any of the foregoing with phosphorous or boron. Electroless deposition would result in co-deposition of P and/or B with said metal or alloy, e.g. nickel, cobalt, nickel-cobalt, nickel-phosphorous, nickel-boron, cobalt-phosphorous, cobalt-boron, nickel-cobalt-phosphorous, nickel-cobalt-boron, nickel-cobalt-phosphorous-boron, nickel-tungsten, cobalt-tungsten, nickel-cobalt-tungsten, nickel-tungsten-phosphorous, nickel-tungsten-boron, cobalt-tungsten-phosphorous, cobalt-tungsten-boron, nickel-cobalt-tungsten-phosphorous, nickel-cobalt-tungsten-boron, nickel-cobalt-tungsten-phosphorous-boron, palladium, palladium-phosphorous, palladium-boron, palladium-nickel and platinum.

The copper electrolyte is typically maintained at a temperature of between about 15° C. and about 70° C., more preferably at a temperature of about 30° C.-35° C.

The invention will now be illustrated with reference to the following non-limiting examples:

### EXAMPLE 1

500 grams of copper nitrate hemi(pentahydrate) were dissolved in 1 liter deionized water (pH=1.74) and then poured into a 267 mL hull cell. A polished brass panel was prepared for electroplating using the following process sequence:
1. MacDermid Dyclean EW cathodic electrocleaner—60° C., 4 amperes, 30 seconds
2. DI water rinse, 5 seconds
3. 10% v/v sulfuric acid activation, 5 seconds
4. DI water rinse, 5 seconds

The panel was plated at 5 amperes, 3 minutes at 25° C. without air agitation. The cell voltage was 8 volts. A uniform salmon-pink matte deposit was obtained from about 0.1 A/dm² to about 20 A/dm². No HCD burn was observed.

### EXAMPLE 2

The electrolyte was prepared as described in Example 1 except that 120 grams of potassium nitrate and 225 mg of sodium chloride were added (pH=1.87) and poured into a 267 mL Hull cell. A polished brass panel was prepared for electroplating as in Example 1. The panel was plated at 5 amperes for 3 minutes at 25° C. without air agitation. The cell voltage was 6.8 volts. Smooth uniform salmon-pink matte deposit was obtained from about 0.1 A/dm² to about 20 A/dm². No HCD burn was observed.

### EXAMPLE 3

40 mL of the electrolyte prepared as described in Example 2 was diluted with DI water to 267 mL (pH=3.45) and poured into a Hull cell. A polished brass panel was prepared for electroplating as in Example 1 and plated at 1.5 amperes for 5 minutes at 25° C. with air agitation. A uniform salmon-pink matte deposit was obtained from about 0.1 A/dm² to about 6 A/dm² current density range. No HCD burn was observed.

### EXAMPLE 4

10 mL/L MacDermid HiSpec2 Brightener and 2 mL/L MacDermid HiSpec2 Wetter were added to 267 of the electrolyte prepared as in Example 3 (pH=3.45) and poured into a Hull cell. A polished brass panel was prepared for electroplating as in Example 1 and plated at 1.5 amperes, 5 minutes at 25° C. with air agitation. A uniform bright deposit was obtained from about 0.1 A/dm² to about 6 A/dm² current density range. No HCD burn was observed.

### COMPARATIVE EXAMPLE 1

In order to compare the proposed electrolyte with a conventional acid copper bath, a 20 liter quantity of each bath was made up with 20 g/L copper and the same organic additives (i.e., wetter and brightener) at the same concentration. The formulae for the two baths are set forth in Table 1 below.

TABLE 1
Acid Copper and Proposed Copper Electrolyte Formulae

| Component | Add Copper Bath | Proposed Bath | Units |
|---|---|---|---|
| Copper | 20.0 | 20.0 | g/L |
| MacDermid Helios EP 603 | 29.05 | | % |
| Sulfuric Acid | 4.57 | | % |
| Free sulfuric equivalent | 80.0 | | g/L |
| Copper nitrate × 2.5 H₂O | | 75.0 | g/L |
| Potassium nitrate | | 120.0 | g/L |
| Acetic acid | | 10.0 | mL/L |
| MacDermid HiSpec2 | 10 | 10 | mL/L |
| Brightener | | | |
| MacDermid HiSpec2 | 2 | 2 | mL/L |
| Wetter | | | |
| Chloride | 70 | 70 | ppm |
| Makeup pH | 0.6 | 1.2 | |

A set of laser ablation-patterned 156×156 mm multi-crystalline silicon substrates, 85 Ω/sq. emitter were copper plated in light-induced plating (LIP) mode in the CupCellPlate tool, available from RENA GmbH, at a range of current densities. The mass gains were compared to theoretical values to determine cathode efficiency. The following process sequence was used:

TABLE 2
Experimental Plating Conditions for Each Wafer

| Process Step | Process Parameters |
|---|---|
| Si Prep | MacDermid Helios SiPrep 914, pH 7.0, 1 min., 30° C. |
| DI Rinse | 15 seconds |
| Ni LIP | MacDermid Helios Nickel EP 610 (per TDS), |
| | pH 4.5, 3 min. 30° C. 200 mA |
| Cu LIP | Acid Cu and proposed bath at 30° C., |
| | 250/500/750 mA; 20.5/10.25/6.75 min. |
| Silver LIEP | 1 minute, 30° C. (final finish) |

The plated wafers were visually inspected by SEM. Quantitative adhesion results were obtained for some of the plated wafers. The method consisted of spot-soldering Sn/Pb/Ag ribbon by hand at a soldering iron temperature of 360° C., and then peeling at a 45° angle using a Condor 70 peel strength bond tester, available from XYZTEC, Inc.

TABLE 3
Plating data for Copper Bath Comparisons

| Cell | Electro- | T | I_{c} | CD | Time | Mass Δ | Mass Δ | Cath. |
|---|---|---|---|---|---|---|---|---|
| ID | lyte | (° C.) | (mA) | (ASD) | (min.) | (act.) | (theor.) | (η) |
| 66 | Acid Cu | 30 | 750 | 8.1 | 6.75 | 74.8 mg | 100 mg | 74.8% |
| 67 | Acid Cu | 30 | 500 | 5.4 | 10.25 | 79.4 mg | 100 mg | 79.4% |
| 68 | Acid Cu | 30 | 250 | 2.7 | 20.5 | 82.6 mg | 100 mg | 82.6% |
| 70 | Pro- | 30 | 250 | 2.7 | 20.5 | N/A | 100 mg | N/A |
| | posed | | | | | | | |
| 71 | Pro- | 30 | 500 | 5.4 | 10.25 | 96.0 mg | 100 mg | 96.0% |
| | posed | | | | | | | |
| 72 | Pro- | 30 | 750 | 8.1 | 6.75 | 91.0 mg | 100 mg | 91.0% |
| | posed | | | | | | | |

All cells exhibited a bright, uniform copper color after plating. Cell ID No. 70 was broken. The proposed formula exhibited higher cathode efficiencies, especially at a high current density.

The proposed bath copper formula has a smoother morphology at higher current density, while the acid copper formula is rougher and grainier. This could lead to higher line resistance for plated cells, and the lower cathode efficiency would require longer dwell times to achieve the desired plating mass.

The median peel strength of the proposed copper process samples was approximately 4-5 times higher than that of the ones plated in a conventional acid copper process. Even though the acid copper bath was made up with very low sulfuric acid concentration, the bath exhibited extremely low adhesion values that would render solar cell contacts non-functional. In contrast, the proposed mildly-acidic copper formulation demonstrated a clear advantage in functional plating tests at high current density, in plating efficiency, adhesion and deposit quality.

Due to the relatively low solubility of copper sulfate, both electrolytes were made up at correspondingly low concentrations (i.e., 20 g/L) of copper. Copper LIP process users will very likely push high current density limits in practice since copper plating is approximately 3 times slower than silver plating at equivalent current densities. The proposed formulation is unique in a sense that the copper concentration in the formulation can easily be increased six fold or higher, which would allow for plating the contacts at correspondingly higher current densities, while maintaining the cathode efficiency, thereby increasing the productivity of the metallization process accordingly. Higher productivity reduces the costs of the solar cell manufacturing process which can help to bring the PV cost per watt down below the level of fossil fuel-based energy cost, while increasing the energy conversion efficiency.

What is claimed is:

1. A method of plating an electrical contact on a semiconductor solar cell substrate, wherein a first surface of the semiconductor solar cell substrate is covered with an anti-reflection coating and a second surface of the semiconductor solar cell substrate comprises a back electrode, wherein a grid pattern is formed in the anti-reflection coating comprising portions with the anti-reflection coating and portions without the anti-reflection coating, and a barrier metal is deposited on the grid pattern formed in the anti-reflection coating on the portions without anti-reflection coating either directly on the semiconductor solar cell substrate or on a silver paste, wherein copper metal is plated on the barrier metal by a process comprising the steps of:
a) immersing the semiconductor solar cell substrate in an electrolyte comprising a copper nitrate salt and wherein an anode is also immersed with the electrolyte;
b) causing the barrier metal to become cathodic by (i) exposing the first surface of the semiconductor solar cell substrate to electromagnetic radiation to generate a photovoltaic response and cause the semiconductor solar cell substrate to generate current in the electrolyte and/or (ii) applying an external current;
wherein copper metal is plated on the barrier metal;
and wherein the grid pattern is formed by either 0) directly removing portions of the anti-reflection coating, or by (ii) printing the silver paste in the image of the grid pattern on the anti-reflection coating and heating the semiconductor solar cell substrate to cause the silver paste to penetrate the anti-reflection coating.

2. The method according to claim 1, wherein the copper nitrate salt is anhydrous copper nitrate, a hydrated copper nitrate, or combinations of one or more of the forgoing.

3. The method according to claim 1, wherein the copper nitrate salt is copper nitrate hemi(pentahydrate).

4. The method according to claim 1, wherein the concentration of copper in the electrolyte is between about 10 g/L and about 150 g/L.

5. The method according to claim 1, wherein the electrolyte further comprises potassium nitrate or sodium nitrate.

6. The method according to claim 5, wherein the concentration of potassium nitrate or sodium nitrate in the electrolyte is between about 100 g/L and about 150 g/L.

7. The method according to claim 1, wherein the electrolyte further comprising a source of chloride ions.

8. The method according to claim 1, wherein the electrolyte comprises one or more additives selected from the group consisting of buffering agents, brighteners, wetters, wetting agents, suppressors, accelerators, cuprous ligands, and combinations thereof.

9. The method according to claim 1, wherein the pH of the electrolyte is between about 1 and 4.

10. The method according to claim 1, wherein the electrolyte does not contain any free sulfuric acid.

11. The method according to claim 1, comprising the step of depositing a final finish of (i) a metal more noble than copper or (ii) tin over the copper.

12. The method according to claim 1, wherein the barrier metal is selected from the group consisting of nickel, cobalt, palladium, tungsten, molybdenum, rhenium, chromium, platinum and alloys of any of the foregoing with phosphorus or boron.

13. The method according to claim 1, wherein the barrier metal is deposited by a light induced plating process.

14. The method according to claim 1, wherein the electrolyte is maintained at a temperature of between about 25° C. and about 35° C.
